(19) United States
(12) Patent Application Publication
(10) Pub. No.: US 2011/0193201 A1
(43) Pub. Date: Aug. 11, 2011

(54) METHOD TO FABRICATE AND TREAT A STRUCTURE OF SEMICONDUCTOR-ON-INSULATOR TYPE, ENABLING DISPLACEMENT OF DISLOCATIONS, AND CORRESPONDING STRUCTURE

(75) Inventors: Oleg Kononchuk, Grenoble (FR); Eric Guiot, Goncelin (FR); Fabrice Gritti, Voiron (FR); Didier Landru, Champ Pres Froges (FR); Christelle Veytizou, Bernin (FR)

(73) Assignee: S.O.I.TEC SILICON ON INSULATOR TECHNOLOGIES, Crolles Cedex (FR)

(21) Appl. No.: 13/126,376

(22) PCT Filed: Oct. 9, 2009
(86) PCT No.: PCT/EP2009/063152

§ 371 Date: Apr. 27, 2011

(30) Foreign Application Priority Data
Oct. 28, 2008 (FR) 08 57329

(51) Int. Cl. H01L 29/04; H01L 21/762

(52) U.S. Cl. 257/627; 438/458; 257/E21.568; 257/E29.004

(57) ABSTRACT

The present invention notably concerns a method to fabricate and treat a structure of semiconductor-on-insulator type, successively comprising a carrier substrate (1), an oxide layer (3) and a thin layer (2) of semiconducting material, according to which: 1) a mask is formed on said thin layer (2) so as to define exposed regions (20), on the surface of said layer, which are not covered by the mask; 2) heat treatment is applied so as to urge at least part of the oxygen of the oxide layer (3) to diffuse through the thin layer (2), leading to controlled removal of the oxide in the regions (30) of the oxide layer (3) corresponding to the desired pattern; characterized in that said carrier substrate (1) and thin layer (2) are arranged relative to each other so that their crystal lattices, in a plane parallel to their interface (I), together form an angle called a “twist angle” of no more than 1°, and in a plane perpendicular to their interface (I) an angle called a “tilt angle” of no more than 1°, and in that a thin layer (2) is used whose thickness is less than 1100 Å.

The invention particularly concerns a method to treat a structure of semiconductor-on-insulator type (SOI) successively comprising a carrier substrate, an oxide layer and a thin semiconducting layer, in which heat treatment is applied under a controlled neutral or reducing atmosphere, and under controlled conditions of time and temperature, so as to urge at least part of the oxygen of the oxide layer to diffuse towards the thin semi-conducting layer, which leads to full or partial dissolution of the oxide layer.

This treatment is applied selectively i.e. to fully dissolve the oxide layer in determined regions of the SOI structure, corresponding to a desired pattern, whilst maintaining the initial oxide layer in the other regions.

The expression is then used of “selective dissolution” of the oxide layer.

In this way a hybrid structure can be obtained i.e. comprising both “SOI” regions in which the oxide layer has been maintained, and bulk regions in which the oxide layer has been fully dissolved.

Said structure can be used for the fabrication of electronic components of different types (e.g. memory components and logic components) which are normally fabricated on different carriers.

Manufacturers of microprocessors have each developed fabrication technologies for logic and memory components, but these two types of components are generally fabricated on respective different carriers (i.e. bulk substrate or SOI).

Also, the changing from one type of substrate to another implies major changes in the fabrication technology.

The advantage of selective dissolution is therefore to provide a microprocessor manufacturer with a wafer comprising “bulk” and “SOI” regions on which, whilst maintaining the technologies they master, they are able to fabricate both “logic” components and “memory” components.

The accuracy of the selective dissolution technique effectively allows control over “bulk” and “SOI” regions on the scale of the components.

Selective dissolution can be implemented by forming a mask on the surface of the thin semiconducting layer, and by applying heat treatment to promote diffusion of the oxygen.

Since the mask is made in a material forming an oxygen-diffusion barrier, the oxygen is only able to diffuse through the exposed regions of the thin semiconducting layer that are not covered by the mask.

During this operation, the problem arises of the presence of defects related to accommodation of the crystal lattices, at the carrier substrate/thin layer interface, in the regions in which the oxide has been removed.

This is called “misfit dislocations”.

The origin of these defects lies in the imperfect aligning of the crystal lattices of the thin layer and of the carrier substrate, in the regions in which they are bonded to each other (i.e. where the oxygen is no longer present).

For as long as the oxide is present between these two lattices, the defects do not appear.

On the other hand, as soon as dissolution of the oxide is obtained, the imperfect alignment of the lattices leads to the formation of these dislocations.

One of the purposes of the invention is to propose a method such as set forth above with which it is possible to minimize, even eliminate, dislocation problems.

It is therefore a method to fabricate and treat a structure of semiconductor-on-insulator type successively comprising a carrier substrate, an oxide layer and a thin layer of a semi-conducting material, obtained by:

a) bonding a donor substrate onto said carrier substrate, said donor substrate comprising said semi-conducting layer, these substrates having identical crystal orientation;

b) thinning said donor substrate so as only to leave said thin layer,
one and/or the other of said carrier substrate and thin layer being coated with an oxide layer;
each of said carrier substrate and thin layer, in a plane parallel to their interface, respectively having a first and a second crystal lattice;

according to which:

1) a mask is formed on said thin layer, so as to define exposed regions on the surface of said layer which are not covered by the mask and are distributed according to a desired pattern;

2) heat treatment is applied under a controlled neutral or reducing atmosphere, and under controlled conditions of time and temperature, so as to urge at least part of the oxygen of the oxide layer to diffuse through the thin layer, leading to the controlled removal of the oxide in the regions of the oxide layer corresponding to said desired pattern.

This method is noteworthy in that:
at step a), said carrier substrate and thin layer are arranged relative to each other so that said crystal lattices, in said plane parallel to their interface, together form a so-called “twist angle” of no more than 1°, and in a plane perpendicular to their interface a so-called “ tilt angle” of no more than 1°.
a thin layer is used whose thickness is less than 1100 Angströms.

The present applicant has evidenced that by limiting alignment defects to the above-specified angles and by making use of a thin layer having the indicated thickness, the dislocations which form at the interface are displaced by the heat treatment applied as far as the free face of the thin layer, where they are dissipated by atomic rearrangement. In other words, the crystal defects are mobile in the thin layer and have a tendency to “rise” to the surface thereof through crystal reorganization.

In the entirety of the present application, by “these substrates have identical crystal orientation>>it is meant that these substrates are cut from the ingots from which they derive substantially along the same axis.

According to other advantageous, non-limiting characteristics:
at step a), said carrier substrate and thin layer are arranged so that said crystal lattices, in said plane parallel to their interface, together form a so-called “twist angle”, of no more than 0.5°;
at step a), the carrier and donor substrates used each carry at least one visual mark oriented in a determined direction with respect to said crystal lattices;
a thin layer is used whose thickness is less than 800 Angströms;
at step b), said donor substrate is treated so as only to leave said thin layer, by fracture of the donor substrate along a previously formed stress region;
at step b) said donor substrate is treated by reducing its thickness via its rear face so as only to leave said thin layer;
   a carrier substrate in silicon is used;
a thin layer is used, notably silicon-based, having a thickness of between 100 and 200 Angströms.

The invention also relates to a structure of semiconductor type which comprises a carrier substrate and a thin layer in a semiconductor material, characterized by the fact that:
said thin layer comprises buried oxide regions, so that there are first regions in which said thin layer is carried by the buried oxide regions, and second regions in which said thin layer is carried by the carrier substrate;
the material of said thin layer located on said oxide regions, and the material of said carrier substrate also located on these regions, have crystal lattices which, in a plane parallel to their interface, together form a so-called “twist angle” of no more than 1° and, in a plane perpendicular to their interface, a so-called “tilt angle” of no more than 1°;
the material of said thin layer located between the oxide regions and directly in contact with the carrier substrate has the same crystal lattice orientation as the material of this carrier substrate.

Advantageously:
the structure has dislocations at the periphery of the second regions i.e. where the thin layer, carried by the carrier substrate, is in contact with the buried oxide regions.
the thickness of said thin layer is less than 1100 Angströms;
the buried oxide thickness lies between 10 and 20 nanometres;
the carrier substrate is in silicon {1,0,0}.

Other characteristics and advantages of the present invention will become apparent on reading the following description of a preferred embodiment.

This description is made with reference to the appended drawings in which:

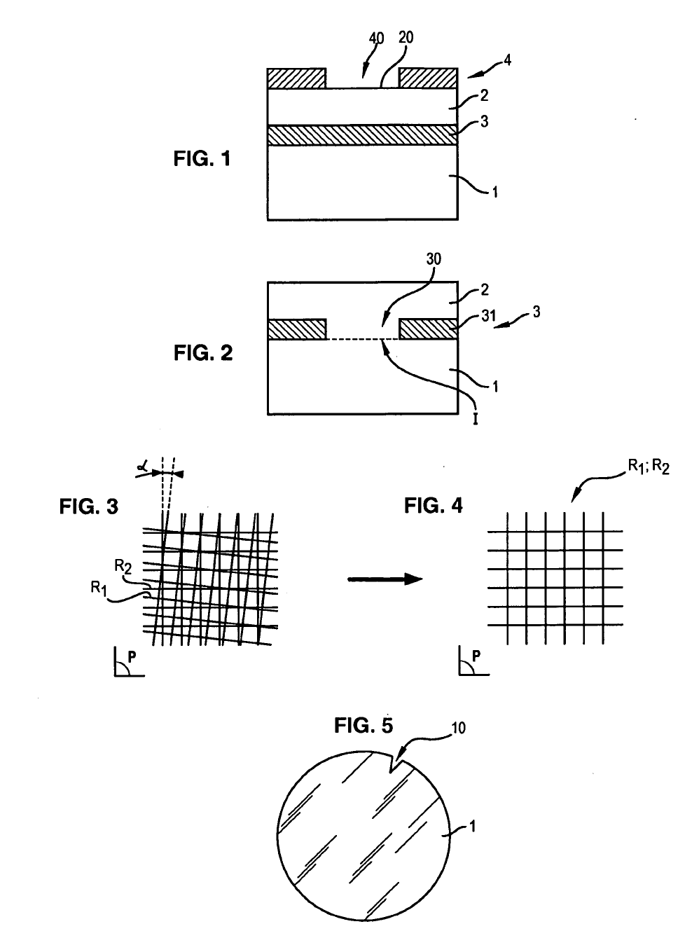

FIGS. 1 and 2 are simplified cross-sectional views of a structure subjected to the method of the invention, in two different states;

FIG. 3 is a diagram illustrating the misalignment of the crystal lattices of the carrier substrate and thin layer of the structure, in a plane parallel to their interface and before implementing the method, whilst

FIG. 4 illustrates the alignment of these lattices after implementation of the method;

FIG. 5 is an overhead view of the carrier substrate used;

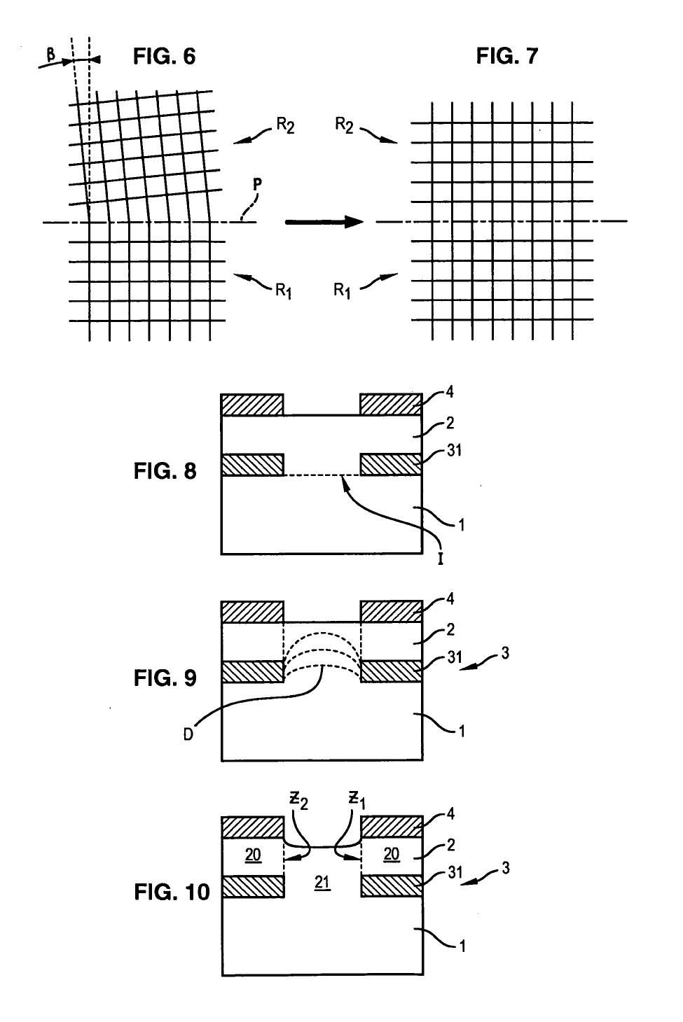

FIGS. 6 and 7 are similar views to FIGS. 3 and 4, intended respectively to illustrate misalignment and alignment of the crystal lattices of the carrier and thin layer substrates, in a direction perpendicular to their interface plane;

FIGS. 8 to 10 are simplified views similar to FIGS. 1 and 2, showing a structure in three different states, corresponding to the embodiment of the invention.

Before starting the actual description of the present method, with reference to the above-cited figures, a few reminders, definitions and techniques are explained below.

Presentation of selective (or local) dissolution treatment:

Selective dissolution treatment is applied to a structure of semiconductor-on-insulator type (SOI) successively comprising, from its base towards its surface, a carrier substrate, an oxide layer and a semiconductor layer.

The means to obtain said SOI structure are described in detail below.

The selective dissolution process comprises the following steps:
forming a mask on the thin semiconducting layer so as to define so-called exposed regions, on the surface of said layer, which are not covered by the mask and are distributed in a desired pattern,
applying heat treatment under a neutral or reducing controlled atmosphere, and under controlled time and temperature conditions, so as to urge at least part of the oxygen of the oxide layer to diffuse through the thin semiconducting layer, leading to the controlled reduction of the oxide thickness in the regions of the oxide layer corresponding to the desired pattern.

Formation of the mask:

The mask is formed selectively on the semiconductor layer .so as to leave exposed those regions of the semiconductor layer corresponding to the regions of the oxide layer in which it is desired to reduce the oxide thickness.

By <<corresponding to>> is meant here that the pattern defined by all the exposed regions of the semiconductor layer is identical to the desired pattern, the regions of the oxide layer in which it is desired to reduce the oxide thickness being distributed accordingly.

In other words, the mask only covers those regions of the semiconductor layer which are complementary to the desired pattern.

In general, selective formation of the mask is performed by using conventional photolithography techniques which allow defining of the regions of the semiconductor layer on which the mask is to be deposited.

Typically, the process to form the mask comprises the following successive steps:
Forming a layer of silicon nitride SixNy (e.g.

Si3N4), which is able to form the mask on the entire surface of the semiconductor layer by deposit;
Depositing a photoresist layer on the entire surface of the SixNy layer;
Local insulation of the resin through a photolithographic mask;
Selective removal of the insulated regions, by dilution in a solvent for example;
Then etching, through the openings formed in the resin, of the regions of the SixNy layer which are then exposed. Etching is typically dry (plasma) etching against which the resin resists. On the other hand the SixNy is etched by this plasma.

It is to be noted that the above-described techniques are routinely used in microelectronics, and that they are given solely by way of example. Generally any process allowing the formation of mask can be used in the invention.

The mask is in a material which forms a barrier to the diffusion of oxygen atoms.

Also, it is able to withstand treatment conditions.

Therefore, silicon nitride (of general formula SixNy in which the stoichiometric coefficients (x, y) may assume different values) is a preferred material to form the mask since it is easy to use (i.e. to deposit then to remove after the dissolution treatment) and does not contaminate the silicon.

However, any other material forming a barrier against the diffusion of oxygen and withstanding the treatment conditions can be used for the mask.

The thickness of the mask typically ranges from 1 to 50 nm and is preferably in the order of 20 nm.

After the dissolution treatment, the mask can be removed by dry or wet etching.

Dissolution treatment:

In the remainder of the description, the example taken is application of the dissolution treatment to a structure in which the thin semiconducting layer is in silicon i.e. a “silicon-on-insulator” structure (SOI).

The mechanisms of oxide dissolution in a SOI structure are described in detail in the article by O. Kononchuk et al, “Internal Dissolution of Buried Oxide in SOI Wafers”, Solid State Phenomena Vols. 131-133 (2008) pp 113-118, to which reference may be made.

During the treatment, the SOI structure is placed in an oven in which a gas flow is generated to form a neutral or reducing atmosphere.

The gas flow may therefore contain argon, hydrogen and/or a mixture thereof.

It is important to note that the phenomenon of dissolution only occurs if there is a sufficient gradient between the concentration of oxygen in the atmosphere and the concentration of oxygen on the surface of the oxide layer.

Therefore, it is considered that the oxygen content of the atmosphere in the oven must be less than 10 ppm which, taking leakage into account, requires an oxygen content in the gas flow of less than 1 ppb.

In this respect, reference may be made to the article by Ludsteck et al, “Growth model for thin oxides and oxide optimization”, Journal of Applied Physics, Vol. 95, No. 5, Mars 2004.

These conditions cannot be obtained in a conventional oven, which generates too much leakage to allow such a low content to be reached; the oven must be specially designed for an optimum seal (reduction in the number of parts to avoid joints, use of solid parts . . . ).

On the contrary, an oxygen concentration in the atmosphere of more than 10 ppm halts dissolution and promotes oxidation of the exposed silicon. For a SOI structure, the dissolution treatment is applied at a temperature of between 1100° C. and 1300° C., preferably in the order of 1200° C.

The higher the temperature, the faster the rate of oxide dissolution. However, the treatment temperature must remain below the melting point of silicon.

For example, to dissolve an oxide thickness of 20 Å under a thin layer of silicon of 1000 Å, the heat treatment conditions are: 1100° C. for 2 hours, 1200° C. . for 10 minutes, or 1250° C. for 4 minutes; It is stressed however that these values depend in particular upon the residual oxygen concentration in the dissolution oven. Greater dissolved thicknesses have also been observed.

Initial SOI structure

The dissolution treatment is applied to a structure of semiconductor-on-insulator type (SOI) which, from its base towards its surface, successively comprises a carrier substrate, an oxide layer and a semiconducting layer.

The carrier substrate essentially acts as stiffener for the SOI structure.

For this purpose, it typically has a thickness in the order of a few hundred micrometers.

The carrier substrate may be a solid or a composite substrate i.e. consisting of a stack of at least two layers of different materials.

The carrier substrate may therefore comprise one of the following materials: Si, GaN, sapphire, in their monocrystalline or polycrystalline forms.

The semiconductor layer comprises at least one semiconductor material such as Si, Ge or SiGe.

The semiconductor layer may possibly be composite i.e. consisting of a stack of layers of semiconductor materials.

The material of the semiconductor layer may be monocrysalline, polycrystalline, amorphous. It may or may not be porous, doped or non-doped.

Particularly advantageously, the semiconductor layer is adapted to receive electronic components.

The thin semiconducting layer has a thickness of less than 5000 Å, and preferably less than 2500 Å to allows sufficiently rapid diffusion of the oxygen. The thicker the semiconductor layer, the slower the rate of dissolution of the oxide.

Therefore, the diffusion of oxygen through a semiconductor layer having a thickness of more than 5000 Å is very slow, and on this account of little advantage at industrial level.

The oxide layer is buried in the structure, between the carrier substrate and the semiconductor layer; it is therefore generally called a “Buried Oxide layer” (BOX) in the trade.

The SOI structure is fabricated using any layer transfer technique known to persons skilled in the art, involving bonding.

Amongst these techniques mention may be made of the Smart Cut™ technique which chiefly comprises the following steps:

formation of an oxide layer on the carrier substrate or on a donor substrate comprising the semiconductor layer,

formation of a stress region in the donor substrate, the stress region defining the thin semiconductor layer to be transferred,

bonding the donor substrate onto the carrier substrate, the oxide layer being located at the bonding interface,

fracture of the donor substrate along the stress region to transfer the thin semiconductor layer onto the carrier substrate.

This technique is known to those skilled in the art and will therefore not be further detailed herein. Reference may be made for example to “Silicon-On-Insulator Technology:Materials to VLSI, 2nd Edition” by Jean-Pierre Colinge, Kluwer Academic Publishers, p.50-51.

A technique may also be used which consists of bonding a donor substrate comprising the semiconductor layer onto the carrier substrate, one and/or the other of the substrates being coated with an oxide layer, then of reducing the thickness of the donor substrate via its rear face so as only to leave the thin semiconductor layer on the carrier substrate.

The SOI structure thus obtained is then subjected to conventional finishing treatments (polishing, planarizing, cleaning . . . ).

In these techniques to form the SOI structure, the oxide layer is formed on the donor substrate or on the carrier substrate by heat oxidation (in which case the oxide is an oxide of the oxidized substrate material), or by deposit e.g. of silicon oxide (Si0₂).

The oxide layer may also be a native oxide layer, resulting from natural oxidation of the donor substrate and/or carrier substrate in contact with the atmosphere.

On the other hand, tests conducted on the SOI structures obtained using the SIMOX technique did not allow any oxide dissolution to be observed, which was attributed to an inferior quality of the oxide due to the method used for obtaining this oxide. In this respect, reference may also be made to the article by L. Zhong et al, Applied Physics Letters 67, 3951 (1995).

It is specified that, before proceeding with bonding, it is possible on one and/or the other of the contact surfaces to apply cleaning or plasma activation steps well known to those skilled in the art, in order to strengthen bonding energy.

To limit the time of the dissolution treatment, the oxide layer of the SOI structure generally has a fine or ultra-fine thickness i.e. between 50 and 1000 Å, preferably between 100 and 250 Å.

With reference to FIG. 1, a SOI structure is shown which it is desired to treat in accordance with the method of the present invention.

It consists of a carrier substrate 1, coated with a thin layer of semiconducting material 2, between which there is an oxide thickness 3 which it is desired to dissolve selectively.

The materials used for these different entities and the fabrication technique for this structure are notably those exemplified under the foregoing heading “Initial SOI structure”.

The different thicknesses of the substrates, thin layer and oxide given in FIG. 1 have been chosen simply for easier reading thereof. They do not relate to reality.

Step 1 of the present method consists of forming a mask 4 on the thin semiconducting layer 2, so as to define so-called exposed regions 20 on the surface of this layer, that are not covered by the mask 4 and are distributed according to a desired pattern.

So as not to overload the appended figures unnecessarily, only one exposed region 20 is shown. It extends opposite an “opening” 40 of the mask.

Evidently, in practice, the mask comprises more than one opening 40 and the layer 2 has more than one exposed region 20.

The technique used to deposit the mask is preferably one of those described under the heading “Forming of the mask” set forth above.

To this assembly heat treatment is applied under a controlled neutral or reducing atmosphere, and under controlled time and temperature conditions, so as to urge at least part of the oxygen of the oxide layer 3 to diffuse through the thin semiconducting layer 2, leading to controlled removal of the oxide thickness in the regions of the oxide layer corresponding to the said desired pattern.

This leads to the situation shown FIG. 2. Therefore, the region 30 of the oxide layer 3 which lies directly under an “open” region 40 of the mask 4, is directly subjected to heat treatment, so that the oxide can diffuse through the layer 2. The oxide has therefore disappeared from region 3.

This is not the case for the other regions 31, lying under the mask 4 which forms a shield against the dissolution treatment.

After this treatment, the situation is one in which, in some places, the carrier substrate 1 is in contact with the thin layer 2, along an interface 1.

According to the invention, when bonding the donor substrate comprising the semiconducting layer 2 onto the carrier substrate 1, they are arranged relative to each other so that their constituent crystal lattices in a plane parallel to their interface, together form a so-called “twist angle” of no more than one degree, and in a plane perpendicular to their interface a so-called “tilt angle” of no more than one degree.

FIG. 3 shows these crystal lattices R1 and R2, the first being that of the carrier substrate and the second that of the semiconducting layer. P designates the plane parallel to their interface I.

Angle α therefore corresponds to the angle formed between the crystal lattices R1 and R2 along plane P.

Similarly, with reference to FIG. 6, these lattices are again designated R1 and R2, but in a plane perpendicular to the plane P of the interface. Angle β corresponds to the angle formed between these two crystal lattices.

The applicant has therefore found that by limiting the value of these angles α and β to no more than one degree, and by using a thin layer 2 of thickness less than 1100 Å, the heat treatment applied to obtain selective dissolution of the oxide 3 causes rearrangement of the atoms in the region of the interface, so that the dislocations normally encountered can be moved through the thickness of the thin layer and then disappear by rearrangement of the atoms.

FIGS. 4 and 7 respectively show the lattices R1 and R2 of the carrier and thin layer substrates after this rearrangement. It is ascertained that these crystal lattices are perfectly superimposed.

In one preferred embodiment, a thin layer 2 of less than 700 Å is preferably used, more preferably less than 500 Å.

Also, according to an additional preferred embodiment, provision is made so that the angles α and β are no more than 0.5°.

Achieving good “alignment” of the carrier substrate relative to the thin layer is notably made with the help of visual marks carried by these materials, oriented in a determined direction with respect to the crystal lattices R1 and R2.

These visual marks consist in particular of a notch 10 such as shown FIG. 5 and known per se.

Therefore, regarding angle α (“twist angle”), the alignment of the substrates with respect to each other is made at the time of bonding, by robots previously programmed to align the notches.

Regarding angle β (“tilt angle”), the substrates will have been previously chosen so that this angle does not exceed 1°.

Images of structures obtained according to the method of the invention, taken under transmission electron microscopy, show that with angles α and β of less than 1° (typically in the order of 0.3°, the interface is reconstructed, whereas interface defects and crystal misalignment are observed with greater angles.

FIGS. 8 to 10 give a summary of the operations performed.

FIG. 8 shows the initial state of the structure after dissolution of the oxide, whilst FIG. 9 under reference D shows the “rising” of the dislocations up to the surface of the structure, in regions not protected by the mask.

Finally, FIG. 10 shows the final state of the structure in which the regions 21 of the thin layer 2, without dislocations, comprise peripheral regions Z₁ and Z₂ nonetheless having dislocations which can be used to accommodate the difference in crystalline structure between region 21 and regions 20 (i.e. those lying on the oxide 3).

1. Method to fabricate and treat a structure of semiconductor-on-insulator type, successively comprising a carrier substrate (1), an oxide layer (3) and a thin layer (2) of semiconductor material, obtained by:
a) on said carrier substrate (1) bonding a donor substrate comprising said semiconductor layer (2), these substrates having identical crystal orientation;
b) thinning said donor substrate so as only to leave said thin layer (2),
one and/or the other of said carrier substrate (1) and thin layer (2) being coated with an oxide layer (3);
each of said carrier substrate (1) and thin layer (2), in a plane parallel to their interface, respectively having a first and a second crystal lattice (R1, R2);
according to which:
1) a mask (4) is formed on said thin layer (2), so as to define exposed regions (20) on the surface of said layer, that are not covered by the mask (4) and are distributed in a desired pattern;
2) heat treatment is applied under a controlled neutral or reducing atmosphere, and under controlled time and temperature conditions, so as to urge at least part of the oxygen of the oxide layer (3) to diffuse through the thin layer (2), leading to controlled removal of the oxide in the regions (30) of the oxide layer (3) corresponding to the said desired pattern,
and characterized by the fact that:
at step a), said carrier substrate (1) and thin layer (2) are arranged relative to each other so that said crystal lattices, between them and along said plane (P) parallel to their interface (I), form an angle (α) called a “twist angle” of no more than 1°, and in a plane perpendicular to their interface (I) an angle (β) called a “tilt angle” of no more than 1°.
a thin layer (2) is used whose thickness is less than 1100 Angströms.

2. Method according to claim 1, characterized by the fact that at step a), said carrier substrate (1) and thin layer (2) are arranged so that said crystal lattices (R1, R2) , in said plane parallel to their interface (I), together form a so-called “twist angle” of no more than 0.5°.

3. Method according to any of the preceding claims, characterized by the fact that at step a), a carrier substrate (1) and a donor substrate are used which each carry a visual mark (10) oriented in a determined direction with respect to said crystal lattices (R1, R2).

4. Method according to any of the preceding claims, characterized by the fact that a thin layer (2) is used whose thickness is less than 800 Angströms.

5. Method according to any of the preceding claims, characterized by the fact that at step b), said donor substrate is treated so as only to leave said thin layer (2) by fracture of the donor substrate along a previously formed stress region.

6. Method according to any of claims 1 to 5, characterized by the fact that at step b) said donor substrate is treated by reducing its thickness via its rear face, so as only to leave said thin layer (2).

7. Method according to any of the preceding claims, characterized by the fact that a carrier substrate (1) in silicon is used.

8. Method according to any of the preceding claims, characterized by the fact that a thin layer (2) particularly in silicon oxide is used, having a thickness of between 100 and 200 Angströms.

9. Structure of semiconductor type which comprises a carrier substrate (1) and a thin layer (2) of a semiconductor material, characterized by the fact that:
said thin layer (2) comprises regions (31) of buried oxide (3), so that there are first regions in which said thin layer (2) is carried by the regions (31) of buried oxide (3), and there are second regions in which said thin layer (2) is carried by the carrier substrate (1);
the material of said thin layer (2) located on said regions (31) of oxide (3) and also the material of said carrier substrate (1) located on these regions (31) have crystal lattices which, in a plane (P) parallel to their interface (I), together form an angle (α) called a “twist angle” of no more than 1° and, in a plane perpendicular to their interface (I), an angle (β) called a “tilt angle” of no more than 1;
the material of said thin layer (2) located between the regions (31) of oxide (3) and directly in contact with the carrier substrate (1) have the same crystal lattice orientation as the material of this carrier substrate (1).

10. Structure according to claim 9, characterized by the fact that it has dislocations on the periphery of the second regions i.e. where the thin layer (2) carried by the carrier substrate (1) is in contact with the regions (31) of buried oxide (3).

11. Structure according to claim 9 or 10, characterized by the fact that said thin layer has a thickness of less than 1100 Angströms.

12. Structure according to any of claims 9 to 11, characterized by the fact that the thickness of buried oxide (3) lies between 10 and 20 nanometres.

13. Structure according to any of claims 9 to 12, characterized by the fact that the carrier substrate (1) is in silicon {1,0,0}.
